(19) United States
(12) Patent Application Publication
(10) Pub. No.: US 2025/0182661 A1
(43) Pub. Date: Jun. 5, 2025

(54) DISPLAY PANEL AND TEST METHOD THEREOF AND DISPLAY DEVICE

(71) Applicants: Hefei Visionox Technology Co., Ltd., Hefei (CN); KunShan Go-Visionox Opto-Electronics Co., Ltd., Kunshan (CN)

(72) Inventors: Xi ZHU, Kunshan (CN); Lu ZHANG, Kunshan (CN)

(73) Assignees: Hefei Visionox Technology Co., Ltd., Hefei (CN); KunShan Go-Visionox Opto-Electronics Co., Ltd., Kunshan (CN)

(21) Appl. No.: 18/928,544

(22) Filed: Oct. 28, 2024

(30) Foreign Application Priority Data
Nov. 30, 2023 (CN) 202311634579.2

(51) Int. Cl. G09G 3/00

(52) U.S. Cl. CPC G09G 3/006; G09G 2330/12

(57) ABSTRACT

A display panel and a test method thereof and a display device. The display panel includes a crack detection circuit, a crack detection line, a first test signal line, a first control signal line, a lighting test circuit, a second test signal line, and a second control signal line. In a crack detection mode, the crack detection circuit is turned on in response to a first control signal on the first control signal line, and the lighting test circuit is turned off in response to a second control signal on the second control signal line. In a lighting test mode, the crack detection circuit is turned off in response to the first control signal, the lighting test circuit is turned on in response to the second control signal, and a second test signal on the second test signal line is transmitted to a data line.

### CROSS-REFERENCE TO RELATED APPLICATION

This application claims priority to Chinese Patent Application No. 202311634579.2 filed Nov. 30, 2023, the disclosure of which is incorporated herein by reference in its entirety.

### TECHNICAL FIELD

Embodiments of the present invention relate to the field of display technology and, in particular, to a display panel and a test method thereof and a display device.

### BACKGROUND

With the rapid development of display technology, people have increasingly higher requirements for the display performance of a display device. The existing display panel is usually provided with a crack detection circuit based on panel crack detection (PCD) technology to detect cracks in the display panel.

At present, in the related art, a test circuit occupies relatively large wiring space, which is not conducive to the implementation of a narrow bezel and has a poor detection effect.

### SUMMARY

Embodiments of the present invention provide a display panel and a test method thereof and a display device to reduce the occupied space of a test circuit, implement narrow bezel design, and at the same time, improve the detection effect.

According to an aspect of the present invention, a display panel is provided. The display panel includes multiple data lines, multiple pixel units arranged in array, a crack detection circuit, a crack detection line, a first test signal line, a first control signal line, a lighting test circuit, a second test signal line, and a second control signal line.

The data lines are connected to the pixel units.

The crack detection circuit is connected to the data lines and the crack detection line. The crack detection line is connected between the crack detection circuit and the first test signal line. Alternatively, the crack detection line is connected between the crack detection circuit and the first control signal line.

The lighting test circuit is connected to the data lines and is configured to be turned on in response to the signal on the second control signal line to transmit the test signal on the second test signal line to the data lines.

Optionally, the crack detection line is connected between the crack detection circuit and the first test signal line. The crack detection circuit includes at least one first switch and multiple second switches. The multiple data lines include first data lines and second data lines.

The first switch is connected between a first data line and the crack detection line. The crack detection line is connected to the first test signal line. The control terminal of the first switch and the control terminals of the second switches are connected to the first control signal line. The first switch is configured to turn on or off the first data lines and the crack detection line in response to a first control signal.

A second switch is connected between a second data line and the first test signal line. The second switches are configured to turn on or off the second data lines and the first test signal line in response to a second control signal.

Optionally, different first switches and different second switches are connected to different data lines.

Optionally, the crack detection circuit includes two first switches. The crack detection line includes a first crack detection line and a second crack detection line.

One end of the first crack detection line is connected to one first switch, and the other end of the first crack detection line is connected to the first test signal line.

One end of the second crack detection line is connected to the other first switch, and the other end of the second crack detection line is connected to the first test signal line.

Optionally, a first switch includes a first transistor. A first electrode of the first transistor is connected to the first crack detection line or the second crack detection line. A second electrode of the first transistor is connected to the first data line. The gate of the first transistor is connected to the first control signal line.

The second switch includes a second transistor. A first electrode of the second transistor is connected to the second data line. A second electrode of the second transistor is connected to the first test signal line. The gate of the second transistor is connected to the first control signal line.

Optionally, the display panel includes a display region and a non-display region disposed around at least part of the display region. The crack detection circuit and the crack detection line are located in at least part of the non-display region. The crack detection line is disposed around the display region.

The display panel also includes a data connection line and the data connection line, a the first test signal line, the second test signal line, the first control signal line and a the second control signal line, are located in the non-display region.

Optionally, the pixel units are located in the display region. The emitted colors of multiple pixel units connected to the same data line are the same.

Optionally, the non-display region also includes a first test pad and a first control pad. The first test signal line is connected to the first test pad. The first control signal line is connected to the first control pad.

Optionally, the non-display region also includes a second test pad and a second control pad. The second test signal line is connected to the second test pad. The second control signal line is connected to the second control pad.

Optionally, the second test pad includes a first sub-pad, a second sub-pad, and a third sub-pad. The second test signal line includes a first sub-signal line, a second sub-signal line, and a third sub-signal line. The first sub-signal line is connected to the first sub-pad. The second sub-signal line is connected to the second sub-pad. The third sub-signal line is connected to the third sub-pad. The test signal transmitted by the first sub-signal line, the test signal transmitted by the second sub-signal line, and the test signal transmitted by the third sub-signal line are different. Data lines corresponding to different sub-signal lines are different.

Optionally, the lighting test circuit is connected to a data line through the data connection line.

Optionally, the lighting test circuit includes a third switch. The third switch includes a third transistor. The gate of the third transistor is connected to the second control signal line. A first electrode of the third transistor is connected to the second test signal line. A second electrode of the third transistor is connected to the data connection line.

Optionally, the crack detection line is connected between the crack detection circuit and the first control signal line. The crack detection circuit includes at least one first switch and multiple second switches. The multiple data lines include first data lines and second data lines.

The first switch is connected between a first data line and the first test signal line. The crack detection line is connected between the control terminal of the first switch and the first control signal line. The first switch is configured to turn on or off the first data lines and the first test signal line in response to the first control signal.

A second switch is connected between a second data line and the first test signal line. The control terminals of the second switches are connected to the first control signal line. The second switches are configured to turn on or off the second data lines and the first test signal line in response to the second control signal.

Optionally, the display panel includes a first control pad connected to the first control signal line. The first control signal applied to the first control pad is a direct current voltage signal.

Optionally, the display panel also includes a third control signal line. A driver chip includes a signal output pad. The third control signal line is connected between the driver chip and the first control signal line. The driver chip is configured to transmit the first control signal to the crack detection circuit through the third control signal line.

The first control signal line is connected to the first control pad.

Optionally, a first test signal on the first test signal line is a fixed voltage signal.

Optionally, the size of the first control pad is greater than the size of the third control pad.

Optionally, the third control pad is connected to the first control signal line through the third control signal line.

Optionally, the first control signal on the first control signal line is an alternating current voltage signal.

According to another aspect of the present invention, a test method of a display panel is provided. The display panel includes multiple data lines and multiple pixel units arranged in an array. The data lines are correspondingly connected to the pixel units. The display panel also includes a crack detection circuit, a crack detection line, a first test signal line, a first control signal line, a lighting test circuit, a data connection line, a second test signal line, and a second control signal line. The crack detection circuit is connected to the data lines and the crack detection line. The crack detection line is connected between the crack detection circuit and the first test signal line. Alternatively, the crack detection line is connected between the crack detection circuit and the first control signal line.

The test method of a display panel includes the steps below.

In a crack detection mode, the crack detection circuit is controlled to be turned on in response to the first control signal on the first control signal line, and the lighting test circuit is controlled to be turned off in response to the second control signal on the second control signal line.

In a lighting test mode, the crack detection circuit is controlled to be turned off in response to the first control signal on the first control signal line, and the lighting test circuit is controlled to be turned on in response to the second control signal on the second control signal line.

Optionally, the display panel also includes a first control pad, a second control pad, and a signal output pad. In the crack detection mode, the test method of a display panel includes the steps below.

In a screen body stage, an external device provides the first control signal to the first control pad and the second control signal to the second control pad. The crack detection circuit is controlled to be turned on in response to the first control signal, and the lighting test circuit is controlled to be turned off in response to the second control signal.

In a module stage, the driver chip provides the first control signal to the first control signal line, and a printed circuit board provides the second control signal to the second control signal line. The crack detection circuit is controlled to be turned on in response to the first control signal, and the lighting test circuit is controlled to be turned off in response to the second control signal.

According to another aspect of the present invention, a display device is provided. The display device includes the driver chip and the display panel provided by any embodiment of the present invention.

Optionally, the display panel includes a bonding region. A third control pad is disposed in the bonding region. The driver chip is located in the bonding region. The signal output pad on the driver chip is bonded and connected to the third control pad.

Optionally, the display device also includes a flexible printed circuit. The display panel also includes the first test pad. The flexible printed circuit is configured to be bonded and connected to the first test pad.

In the technical solution provided by the embodiments of the present invention, during the crack detection process of the screen body stage and the module stage of the display panel, the same set of crack detection circuits is shared to reduce the number of crack detection circuits. In this manner, it is beneficial to reducing the wiring space of the crack detection circuit, thereby implementing narrow bezel design. The crack detection circuit and the lighting test circuit are separately controlled by using different control signals. In the crack detection mode, the crack detection circuit is controlled to turn on, and the lighting test circuit is controlled to turn off. The crack detection line is configured to detect whether there are cracks on the screen body. In the lighting test mode, the crack detection circuit is controlled to turn off, and the lighting test circuit is controlled to turn on. The second test signal is transmitted to the corresponding data line. Thus, the crack detection line is prevented from adversely affecting the lighting test, thereby improving the accuracy of the lighting test.

It is to be understood that the content described in this section is neither intended to identify key or critical features of the embodiments of the present invention nor intended to limit the scope of the present invention. Other features of the present invention become easily understood through the description provided hereinafter.

### BRIEF DESCRIPTION OF DRAWINGS

To illustrate the technical schemes of embodiments of the present invention more clearly, the drawings used in the description of the embodiments are briefly described below. Apparently, the drawings described below merely illustrate part of the embodiments of the present invention, and those of ordinary skill in the art may obtain other drawings based on the drawings described below on the premise that no creative work is done.

FIG. 1 is a diagram illustrating the structure of a display panel according to an embodiment of the present invention.

FIG. 2 is a diagram illustrating the structure of another display panel according to an embodiment of the present invention.

FIG. 3 is a diagram illustrating the structure of another display panel according to an embodiment of the present invention.

FIG. 4 is a diagram illustrating the structure of another display panel according to an embodiment of the present invention.

FIG. 5 is a diagram illustrating the structure of another display panel according to an embodiment of the present invention.

FIG. 6 is a diagram illustrating the structure of another display panel according to an embodiment of the present invention.

FIG. 7 is a diagram illustrating the structure of another display panel according to an embodiment of the present invention.

FIG. 8 is a flowchart of a test method of a display panel according to an embodiment of the present invention.

FIG. 9 is a diagram illustrating the structure of a display device according to an embodiment of the present invention.

### DETAILED DESCRIPTION

To make the schemes of the present invention better understood by those skilled in the art, the technical schemes of the embodiments of the present invention are described below clearly and completely in conjunction with the drawings in the embodiments of the present invention. Apparently, the embodiments described below are part, not all, of the embodiments of the present invention. Based on the embodiments of the present invention, all other embodiments obtained by those of ordinary skill in the art are within the scope of the present invention on the premise that no creative work is done.

It is to be noted that terms “first”, “second”, and the like in the description, claims, and drawings of the present invention are used for distinguishing between similar objects and are not necessarily used for describing a particular order or sequence. It is to be understood that the data used in this manner is interchangeable in appropriate cases so that the embodiments of the present invention described herein can be implemented in an order not illustrated or described herein. In addition, terms “comprising”, “including”, and any variation thereof are intended to encompass a non-exclusive inclusion. For example, a process, method, system, product, or device that includes a series of steps or units not only includes the expressly listed steps or units, but may also include other steps or units that are not expressly listed or are inherent to such a process, method, product, or device.

In the related art, a test circuit occupies too much wiring space. According to the research by the inventor, the reason for the preceding problem is that in the related art, a detection method is divided into screen body stage detection and module stage detection. A screen body stage refers to a stage before a display panel is bonded to a driver chip. A module stage refers to a stage where the display panel and the driver chip are bonded.

A crack detection line is usually disposed around a screen body. Since two detection methods are different, during crack detection, it is necessary to use one detection circuit to perform module stage detection and use the other detection circuit to perform screen body stage detection. Thus, two sets of detection circuits (corresponding to two sets of crack detection lines) need to be disposed correspondingly, thereby increasing the wiring space of the detection circuit. In addition, in the screen body stage, when a normal image is detected, PCD testing is performed on two data lines in the image by winding the crack detection line, while the other data lines directly access a test signal through the corresponding test circuit. Due to the load differences between different data lines, interference of a bright line or a dark line may occur in detecting the image. As a result, the determination of the test result is affected.

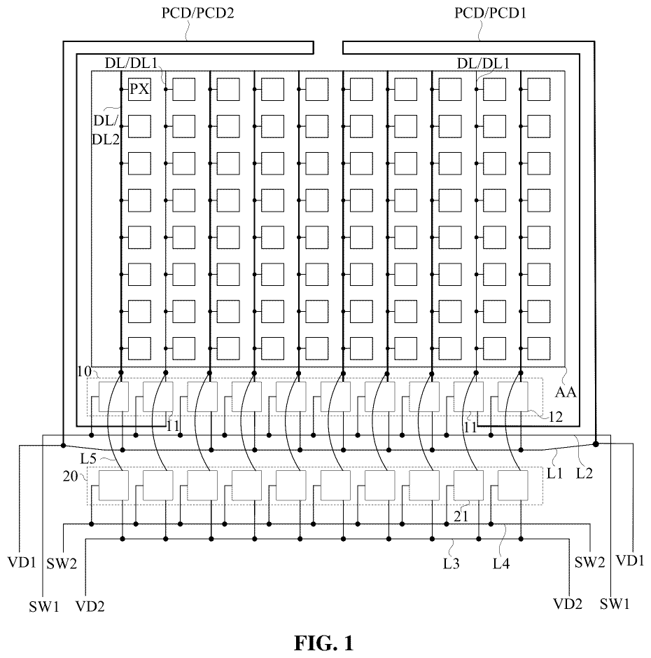

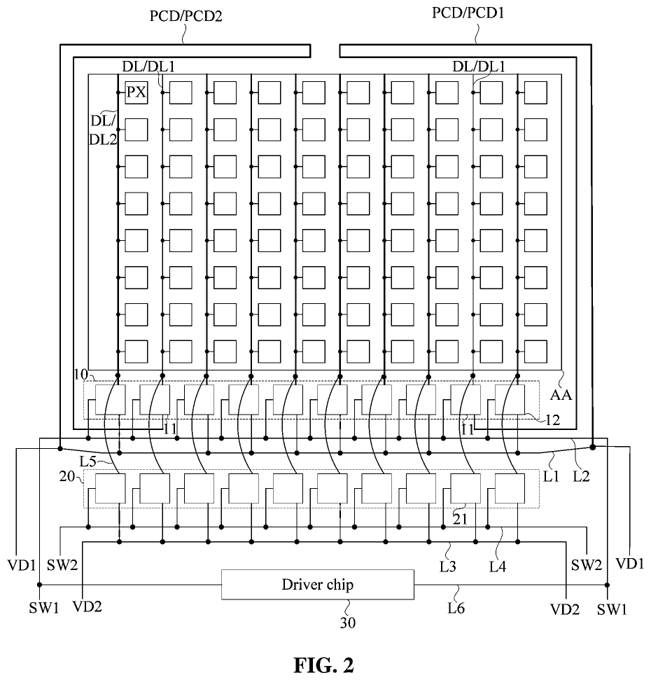

In view of the preceding problems, an embodiment of the present invention provides a display panel. FIG. 1 is a diagram illustrating the structure of a display panel according to an embodiment of the present invention. FIG. 2 is a diagram illustrating the structure of another display panel according to an embodiment of the present invention. FIG. 1 is a diagram illustrating the structure of a display panel when a driver chip is not bonded. FIG. 2 is a diagram illustrating the structure of a display panel after a driver chip is bonded. Referring to FIGS. 1 and 2, the display panel provided in this embodiment includes multiple data lines DL, multiple pixel units PX arranged in an array, a crack detection circuit 10, a crack detection line PCD, a first test signal line L1, a first control signal line L2, a lighting test circuit 20, a second test signal line L3, and a second control signal line L4.

The data lines DL are correspondingly connected to the pixel units PX. Optionally, the data lines DL are correspondingly connected to the pixel units PX, which means that the pixel units PX belonging to the same column are electrically connected to the same data line DL.

The crack detection circuit 10 is connected to the data lines DL and the crack detection line PCD. The crack detection line PCD is connected between the crack detection circuit 10 and the first test signal line L1. Alternatively, the crack detection line PCD is connected between the crack detection circuit 10 and the first control signal line L2.

The lighting test circuit 20 is connected to the data lines DL and is configured to be turned on in response to the signal on the second control signal line L4 to transmit the test signal on the second test signal line L3 to the data lines DL.

In a crack detection mode, the crack detection circuit 10 is turned on in response to a first control signal SW1 on the first control signal line L2 to transmit a first test signal VD1 on the first test signal line L1 to the data lines DL, and the lighting test circuit 20 is turned off in response to a second control signal SW2 on the second control signal line L4.

In a lighting test mode, the crack detection circuit 10 is turned off in response to the first control signal SW1 on the first control signal line L2, and the lighting test circuit 20 is turned on in response to the second control signal SW2 on the second control signal line L4 to transmit a second test signal VD2 on the second test signal line L3 to the data lines DL.

Specifically, each pixel unit PX may include a light-emitting device and a pixel circuit configured to drive the light-emitting device to perform light-emitting display. The pixel circuit may be composed of a thin-film transistor and a storage capacitor. For example, the pixel circuit may be composed of two thin-film transistors and one storage capacitor or may be composed of seven thin-film transistors and one storage capacitor. The thin-film transistor includes a drive transistor and a switch transistor. The pixel circuit is connected to the corresponding data line DL through the switch transistor. When the switch transistor is turned on, the data voltage on the data line DL may be transmitted to the storage capacitor, and the data voltage is stored by using the storage capacitor, so that the drive transistor can generate a drive current according to the data voltage stored in the storage capacitor, thereby driving the organic light-emitting diode to perform light-emitting display.

The pixel circuit in each column of pixel units PX is connected to the same data line DL, and the pixel circuits in different columns of pixel units PX are connected to different data lines DL. If the crack detection circuit 10 is located between the lighting test circuit 20 and the display region of the display panel, the lighting test circuit 20 may be connected to the corresponding data line DL through a data connection line L5 to transmit the second test signal VD2 to the corresponding data line DL and then transmit the second test signal VD2 to a pixel unit PX through a data line DL.

In this embodiment, the crack detection line PCD is connected between the crack detection circuit 10 and the first test signal line L1 or the first control signal line L2 to detect whether a crack occurs on the screen body. When a crack occurs on the screen body, the crack detection line PCD breaks. The first test signal VD1 on the first test signal line L1 or the first control signal SW1 on the first control signal line L2 cannot be transmitted to the corresponding data line DL through the crack detection line PCD. Thus, the pixel unit PX correspondingly connected to the data line DL presents a dark state or a bright state (which is related to the first test signal VD1, if the first test signal VD1 is a black state voltage, the corresponding pixel unit PX presents a bright state, and a bright line appears at the position corresponding to the data line DL; and if the first test signal VD1 is a normal display voltage, the corresponding pixel unit PX presents a dark state, and a dark line appears at the position corresponding to the data line DL).

For example, the crack detection line PCD is connected between the crack detection circuit 10 and the first test signal line L1. In the screen body stage, as shown in FIG. 1, the display panel is not bonded to the driver chip, and each signal is provided by an external device (obtained in a needling manner). In the crack detection mode, the crack detection circuit 10 is turned on in response to the first control signal SW1 on the first control signal line L2, the first test signal VD1 is transmitted on the first test signal line L1, and the lighting test circuit 20 is turned off in response to the second control signal SW2 on the second control signal line L4. For example, the first test signal VD1 is at a high level. Since the crack detection circuit 10 is turned on, the first test signal VD1 is written into the data line DL not connected to the crack detection line PCD, and the pixel unit PX of the corresponding column is in a dark state. If the crack detection line PCD does not break, the first test signal VD1 is also written into the data line DL connected to the crack detection line PCD, and the pixel unit PX of the corresponding column is in a dark state, that is, the pixel units PX of the entire screen are in the dark state. If the crack detection line PCD breaks, the first test signal VD1 cannot be written into the data line DL connected to the crack detection line PCD, the pixel unit PX of the corresponding column is in a bright state, and a bright line appears on the screen body.

In the module stage, as shown in FIG. 2, the display panel is bonded to the driver chip 30. The first test signal VD1 on the first test signal line L1 may be provided by a flexible printed circuit (FPC). The first control signal SW1 on the first control signal line L2 may be provided by the driver chip 30. At this time, in the crack detection mode, for the crack detection circuit 10, the detection method of screen body cracks is the same as the detection method of the screen body stage.

Further, when the crack detection mode is switched to the lighting test mode, that is, when crack detection is not performed, the crack detection circuit 10 is turned off in response to the first control signal SW1 on the first control signal line L2, and the crack detection circuit 10 does not function. The lighting test circuit 20 is turned on in response to the second control signal SW2 on the second control signal line L4, and the second test signal VD2 on the second test signal line L3 is transmitted to the corresponding data line DL through the data connection line L5 to perform a lighting test on a pixel unit PX. In the lighting test mode, since each data line DL receives the second test signal VD2 through the data connection line L5, and the crack detection line PCD does not participate in the lighting test mode, the load corresponding to each data line DL is the same. Thus, the crack detection line PCD may not adversely affect the lighting test mode, and it is beneficial to improving the test accuracy of other images under non-crack detection, thereby improving the test accuracy. The crack detection circuit 10 and the lighting test circuit 20 may work independently in a time-sharing manner without affecting each other.

In the technical solution provided by this embodiment of the present invention, during the crack detection process of the screen body stage and the module stage of the display panel, the same set of crack detection circuits is shared to reduce the number of crack detection circuits. In this manner, it is beneficial to reducing the wiring space of the crack detection circuit, thereby implementing narrow bezel design. The crack detection circuit and the lighting test circuit are separately controlled by using different control signals. In the crack detection mode, the crack detection circuit is controlled to turn on, and the lighting test circuit is controlled to turn off. The crack detection line is configured to detect whether there are cracks on the screen body. In the lighting test mode, the crack detection circuit is controlled to turn off, and the lighting test circuit is controlled to turn on. The data connection line transmits the second test signal to the corresponding data line. Thus, the crack detection line is prevented from adversely affecting the lighting test, thereby improving the accuracy of the lighting test.

Optionally, continuously referring to FIGS. 1 and 2, in an optional embodiment, when the crack detection line PCD is connected between the crack detection circuit 10 and the first test signal line L1, the crack detection circuit includes at least one first switch 11 and multiple second switches 12. The data lines DL includes first data lines DL1 and second data lines DL2.

The first switch 11 is connected between a first data line DL1 and the crack detection line PCD. The crack detection line PCD is connected to the first test signal line L1. The control terminal of the first switch 11 is connected to the first control signal line L2. The first switch 11 is configured to turn on or off the first data lines DL1 and the crack detection line PCD in response to the first control signal SW1 on the first control signal line L2.

A second switch 12 is connected between a second data line DL2 and the first test signal line L1. The control terminals of the second switches are also connected to the first control signal line L2. The second switches 12 are configured to turn on or off the second data lines DL2 and the first test signal line L1 in response to the second control signal SW2 transmitted on the second control signal line L4.

Specifically, different first switches 11 and different second switches 12 are connected to different data lines DL. Optionally, the first switch 11 or the second switches 12 correspond to the data lines DL in a one-to-one manner. For example, the crack detection line PCD includes a first crack detection line PCD1 and a second crack detection line PCD2. The first crack detection line PCD1 and the second crack detection line PCD2 are both located in a non-display region. The first crack detection line PCD1 is disposed around the right half region of the display region AA to identify whether a crack exists in the right half region of the display panel. The second crack detection line PCD2 is disposed around the left half region of the display region AA to identify whether a crack exists in the left half region of the display panel.

The crack detection circuit 10 includes two first switches 11. One end of the first crack detection line PCD1 is connected to one first switch 11, and the other end of the first crack detection line PCD1 is connected to the first test signal line L1. One end of the second crack detection line PCD2 is connected to the other first switch, and the other end of the second crack detection line PCD2 is connected to the first test signal line L1.

Optionally, the lighting test circuit 20 includes a third switch 21. The third switch 21 is connected between the data connection line L5 and the second test signal line L3. The control terminal of the third switch 21 is connected to the second control signal line L4.

Optionally, the crack detection circuit 10 and the lighting test circuit 20 are both located in the non-display region, for example, in a lower bezel region. The crack detection line PCD, the data connection line L5, test signal lines (the first test signal line L1 and the second test signal line L3), and control signal lines (the first control signal line L2 and the second control signal line L4) are both located in the non-display region. The pixel units PX are located in the display region AA. The non-display region is disposed around display region AA. Optionally, the emitted colors of the pixel units PX connected to the same data line DL are the same.

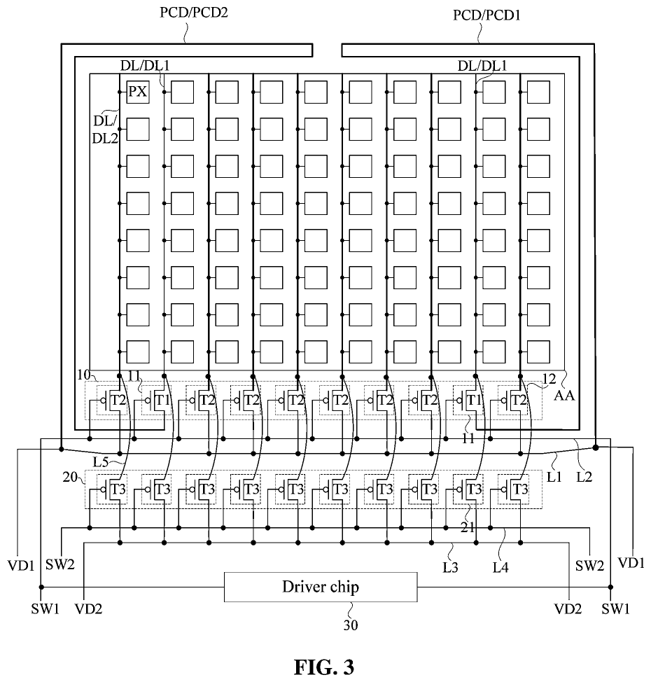

FIG. 3 is a diagram illustrating the structure of another display panel according to an embodiment of the present invention. Referring to FIG. 3, on the basis of the preceding embodiment, optionally, a first switch 11 includes a first transistor T1. A first electrode of the first transistor T1 is connected to the first crack detection line PCD1 or the second crack detection line PCD2. A second electrode of the first transistor T1 is connected to the first data line DL1. The gate of the first transistor T1 is connected to the first control signal line L2. The second switch 12 includes a second transistor T2. A first electrode of the second transistor T2 is connected to the second data line DL2. A second electrode of the second transistor T2 is connected to the first test signal line L1. The gate of the second transistor T2 is connected to the first control signal line L2. The third switch 21 includes a third transistor T3. The gate of the third transistor T3 is connected to the second control signal line L4. A first electrode of the third transistor T3 is connected to the second test signal line L3. A second electrode of the third transistor T3 is connected to the data connection line L5.

Specifically, for example, each transistor is a p-type transistor. In the crack detection mode, the first control signal SW1 is at a low level, and the second control signal SW2 is at a high level. Thus, the first transistor T1 and the second transistor T2 are turned on, and the third transistor T3 is turned off. The first test signal VD1 is at a high level. The second test signal line L3 may not transmit a test signal. The first test signal VD1 is directly transmitted to the corresponding second data line DL2 through the second transistor T2, and each pixel unit PX connected to the second data line DL2 displays a black image. The first test signal VD1 is also transmitted to the first data line DL1 through the crack detection line PCD (the first crack detection line PCD1 and the second crack detection line PCD2) and the first transistor T1. If the crack detection line PCD does not break, the first test signal VD1 is written to the first data line DL1. Each pixel unit PX connected to the first data line DL1 displays a black image, and the entire screen displays the same image. If the crack detection line PCD breaks, the first test signal VD1 cannot be written to the first data line DL1. Each pixel unit PX connected to the first data line DL1 cannot display a black image. Thus, two bright lines (column pixels corresponding to two first data lines DL1) are presented on the entire screen.

The crack detection mode may be the crack detection of the screen body stage or may be the crack detection of the module stage.

In the lighting test mode, the first control signal SW1 is at a high level, and the second control signal SW2 is at a low level. Thus, the first transistor T1 and the second transistor T2 are turned off, and the third transistor T3 is turned on. The first test signal line L1 may not transmit a test signal. The second test signal VD2 transmitted on the second test signal line L3 is at a low level. The second test signal VD2 is directly written to the first data line DL1 and the second data line DL2 through the third transistor T3 and the data connection line L5 and does not need to be written to the first data line DL1 through the crack detection line PCD. Thus, the load of the first data line DL1 and the load of the second data line DL2 are the same, and the image displayed by each pixel unit PX is the same. There is no problem of bright line interference on a black image, and the adverse effect of the crack detection line PCD on the lighting test is effectively avoided.

It is to be understood that in the crack detection mode of the screen body stage and the crack detection mode of the module stage, crack detection is performed by using the crack detection circuit 10. When a lighting test is performed, the crack detection circuit 10 is switched to the lighting test circuit 20, thereby avoiding the adverse effect of the crack detection line PCD on the lighting test.

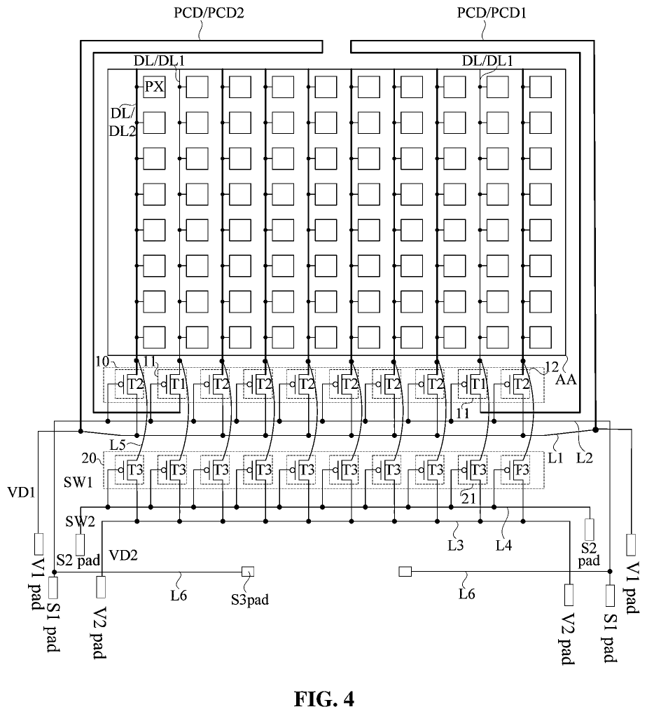

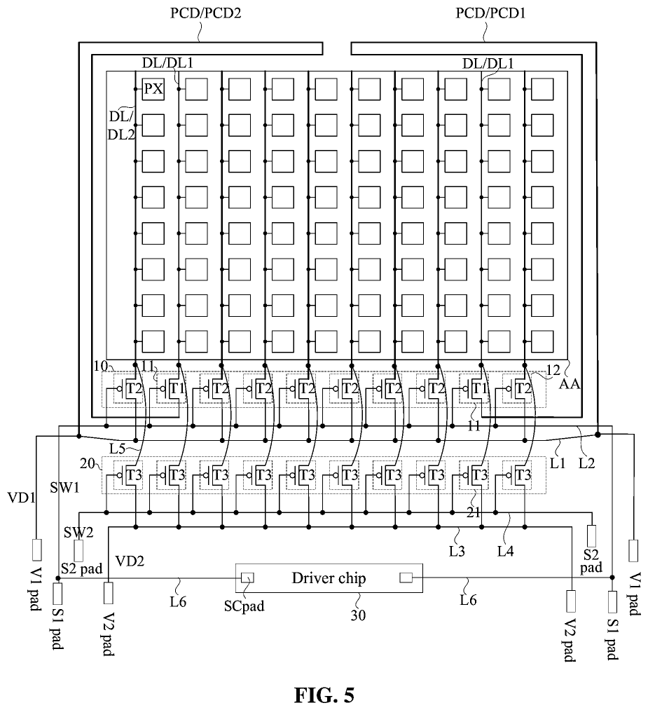

FIG. 4 is a diagram illustrating the structure of another display panel according to an embodiment of the present invention. FIG. 5 is a diagram illustrating the structure of another display panel according to an embodiment of the present invention. The display panel shown in FIG. 4 is a structure without a bonded driver chip. FIG. 5 shows the structure after the driver chip is bonded. Referring to FIGS. 4 and 5, on the basis of the preceding technical solutions, optionally, the non-display region also includes a first test pad V1 pad and a first control pad S1 pad. The first test signal line L1 is connected to the first test pad V1 pad. The first control signal line L2 is connected to the first control pad S1 pad.

The non-display region also includes a second test pad V2 pad and a second control pad S2 pad. The second test signal line L3 is connected to the second test pad V2 pad. The second control signal line L4 is connected to the second control pad S2 pad.

The first test pad V1 pad, the second test pad V2 pad, and the second control pad S2 pad are all bonding pads. The first control pad S1 pad is a non-bonding pad. Specifically, the first test pad V1 pad is configured to receive the first test signal VD1. The second test pad V2 pad is configured to receive the second test signal VD2. The first control pad S1 pad is configured to receive the first control signal SW1. The second control pad S2 pad is configured to receive the second control signal SW2. The first test pad V1 pad, the second test pad V2 pad, the first control pad S1 pad, and the second control pad S2 pad are all located in the non-display region. In the screen body stage, the external device applies a corresponding signal to each pad. In the module stage, the first test pad V1 pad, the second test pad V2 pad, and the second control pad S2 pad are bonded and connected to the FPC. The first control pad S1 pad is connected to the driver chip 30 through a third control signal line L6.

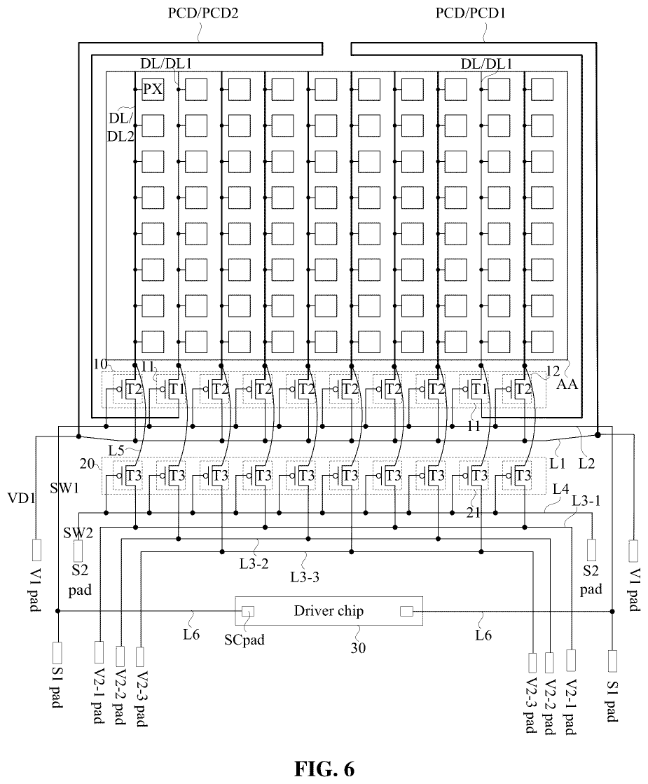

FIG. 6 is a diagram illustrating the structure of another display panel according to an embodiment of the present invention. Referring to FIG. 6, on the basis of the preceding technical solutions, optionally, the second test pad V2 pad includes a first sub-pad V2-1 pad, a second sub-pad V2-2 pad, and a third sub-pad V2-3 pad. The second test signal line L3 includes a first sub-signal line L3-1, a second sub-signal line L3-2, and a third sub-signal line L3-3. The first sub-signal line L3-1 is connected to the first sub-pad V2-1 pad. The second sub-signal line L3-2 is connected to the second sub-pad V2-2 pad. The third sub-signal line L3-3 is connected to the third sub-pad V2-3 pad. The test signal transmitted by the first sub-signal line L3-1, the test signal transmitted by the second sub-signal line L3-2, and the test signal transmitted by the third sub-signal line L3-3 are different. Data lines DL corresponding to different sub-signal lines are different.

For example, the pixel units PX include red sub-pixels, green sub-pixels, and blue sub-pixels. The emitted colors of the sub-pixels corresponding to the pixel units PX in the same column are the same. The first sub-signal line L3-1 may be configured to transmit the test signal corresponding to the red sub-pixels. The second sub-signal line L3-2 may be configured to transmit the test signal corresponding to the green sub-pixels. The third sub-signal line L3-3 may be configured to transmit the test signal corresponding to the blue sub-pixels. When the lighting test is performed, different test signals are applied to the first sub-pad V2-1 pad, the second sub-pad V2-2 pad, and the third sub-pad V2-3 pad respectively and are transmitted to the corresponding data lines DL through the first sub-signal line L3-1, the second sub-signal line L3-2, and the third sub-signal line L3-3 respectively.

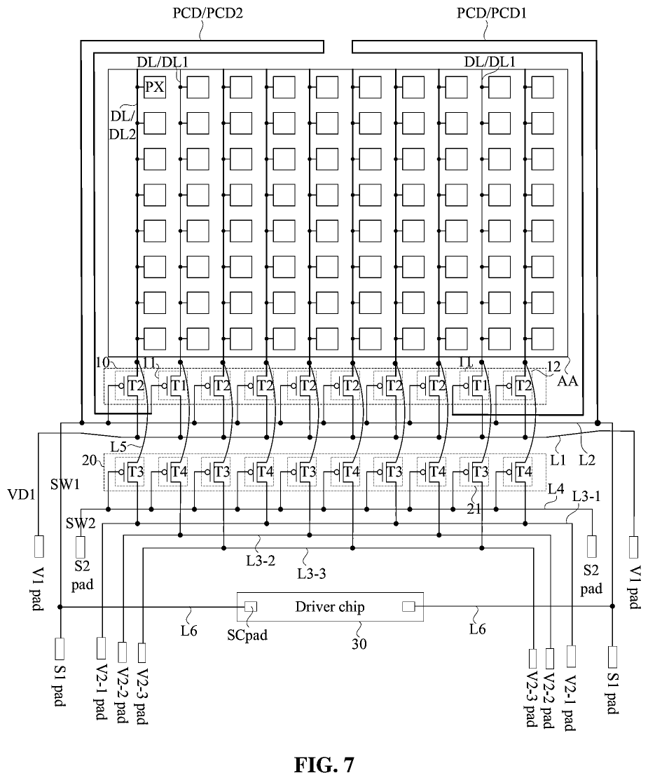

Optionally, in another optional embodiment provided by the embodiments of the present invention, FIG. 7 is a diagram illustrating the structure of another display panel according to an embodiment of the present invention. Referring to FIG. 7, the crack detection line PCD may also be connected between the crack detection circuit 10 and the first control signal line L2. Specifically, the first switch 11 is connected between a first data line DL1 and the first test signal line L1. The crack detection line PCD is connected between the control terminal of the first switch 11 and the first control signal line L2. The first switch 11 is configured to connect or disconnect the first data lines DL1 and the first test signal line L1 in response to the first control signal SW1. A second switch 12 is connected between a second data line DL2 and the first test signal line L1. The control terminals of the second switches 12 are connected to the first control signal line L2.

In the crack detection mode, if the crack detection line PCD (the first crack detection line PCD1 and/or the second crack detection line PCD2) breaks, the first control signal SW1 cannot be transmitted to the control terminal of the first switch 11. The first switch 11 is turned off, the first test signal VD1 is not written into the corresponding first data line DL1, and the pixel unit PX of the corresponding column is in a bright state. The specific detection process may refer to the related description in the preceding embodiments, and the details are not repeated here.

Optionally, continuously referring to FIGS. 4 to 7, in this embodiment, the display panel also includes a third control signal line L6. The third control signal line L6 is connected between the driver chip 30 and the first control signal line L2. The driver chip 30 includes a signal output pad SCpad. The driver chip 30 is configured to transmit the first control signal SW1 to the third control signal line L6.

Specifically, the display panel includes a bonding region. A third control pad S3 is disposed in the bonding region. The third control pad S3 is connected to the first control signal line L2. For example, the third control pad S3 pad may be connected to the first control pad S1 pad through the third control signal line L6, so that the third control pad S3 is connected to the first control signal line L2.

Before the display panel is bonded to the driver chip 30, each test signal and each control signal are provided by a corresponding pad, for example, the external device applies a signal to a pad. After the display panel is bonded to the driver chip 30 (the signal output pad SCpad on the driver chip 30 is bonded and connected to the third control pad S3 pad by conductive adhesive), both the first test signal VD1 and the second test signal VD2 are provided by the FPC, and the first control signal SW1 is provided by the driver chip 30. Since the FPC can provide only a direct current voltage signal, to implement the switching function of the crack detection circuit 10 in different test modes, the first control signal SW1 needs to be a variable signal, that is, an alternating current voltage signal. Thus, in the test mode of the module stage, the display panel can turn off or turn on the crack detection circuit 10 through the first control signal SW1. The first control signal SW1 may be at a high level and a low level at different times.

It is to be noted that in the crack detection mode, even if the lighting test circuit 20 is turned on in response to the second control signal SW2, since there is no second test signal VD2 transmitted on the second test signal line L3, the lighting test circuit 20 may not transmit a signal to the data lines DL. Thus, the second test signal VD2 may be provided by the FPC.

Optionally, the first test signal VD1 transmitted on the first test signal line L1 is a fixed voltage signal.

Optionally, in another optional embodiment provided by the embodiments of the present invention, the first control signal SW1 on the first control signal line L2 may also be an alternating current voltage signal, that is, during the screen body stage detection and the module stage detection, the first control signal SW1 is an alternating current voltage signal. When crack detection is performed, the first control signal line L2 is controlled to transmit a turn-on voltage, so that the crack detection circuit 10 is turned on. When a lighting test is performed, the first control signal line L2 is controlled to transmit a turn-off voltage, so that the crack detection circuit 10 is turned off. Herein, there is no need to dispose the third control signal line L6, and the state of the crack detection circuit 10 may be switched by changing a signal type.

Optionally, the size of the first control pad S1 pad is greater than the size of the third control pad S3 pad. Herein, the first control pad S1 pad is configured to contact a probe in the crack detection mode of the screen body stage. To reduce a contact resistance, the size of the first control pad S1 pad is relatively large. For example, the size of the first control pad S1 pad is 100 μm to ensure the contact area between the pad and the probe. The third control pad S3 pad is a bonding pad and is configured to be bonded and connected to the driver chip 30. The signal output pad SCpad on the driver chip 30 is only about 10 μm. Thus, to ensure the bonding effect and not affect the bonding of other pads on the driver chip 30, the size of the third control pad S3 pad is relatively small to satisfy the bonding requirement of the driver chip 30.

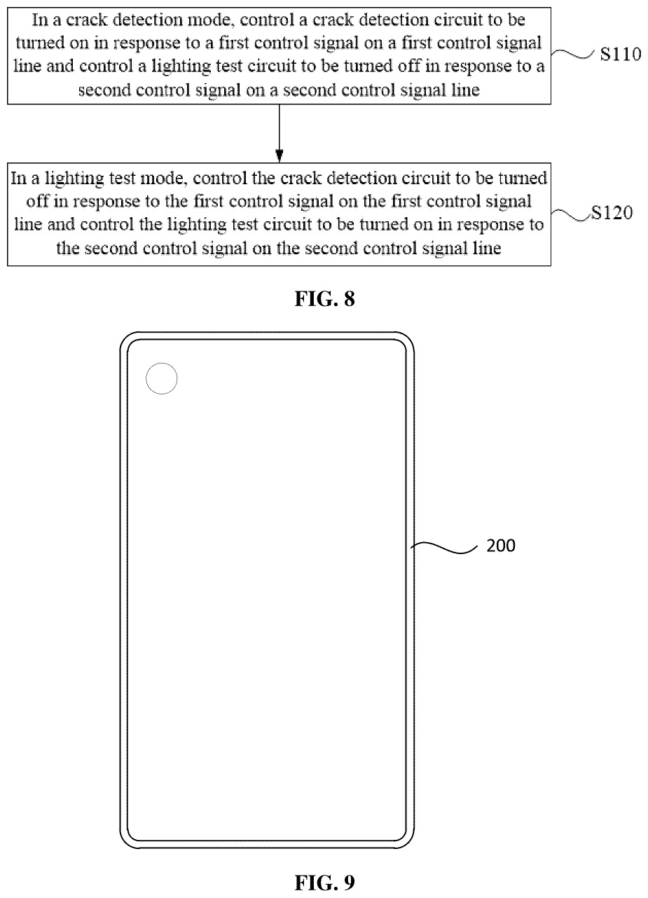

An embodiment of the present invention provides a test method of a display panel. FIG. 8 is a flowchart of a test method of a display panel according to an embodiment of the present invention. Referring to FIG. 8, the test method of a display panel includes the steps below.

In S110, in the crack detection mode, the crack detection circuit is controlled to be turned on in response to the first control signal on the first control signal line, and the lighting test circuit is controlled to be turned off in response to the second control signal on the second control signal line.

In S120, in the lighting test mode, the crack detection circuit is controlled to be turned off in response to the first control signal on the first control signal line, and the lighting test circuit is controlled to be turned on in response to the second control signal on the second control signal line.

Specifically, in the crack detection mode, the test method of a display panel includes the steps below.

In the screen body stage, the external device provides the first control signal to the first control pad and the second control signal to the second control pad. The crack detection circuit is controlled to be turned on in response to the first control signal, and the lighting test circuit is controlled to be turned off in response to the second control signal.

In the module stage, the driver chip provides the first control signal to the first control signal pad, and a printed circuit board provides the second control signal to the second control signal pad. The crack detection circuit is controlled to be turned on in response to the first control signal, and the lighting test circuit is controlled to be turned off in response to the second control signal.

For example, referring to 5, in the crack detection mode, if no crack occurs in the display panel, the first test signal VD1 is transmitted to the corresponding pixel unit PX through the first test signal line L1, the crack detection line PCD, the first switch 11, and the first data line DL1 and is transmitted to the corresponding pixel unit PX through the first test signal line L1, the second switch 12, and the second data line DL2. Each column of pixel units PX in the display panel may receive the first test signal VD1 and control the light-emitting device to display a corresponding image according to the first test signal VD1. The image displayed by each column of pixel units PX is the same. In the screen body stage, the first test signal VD1 is acquired by the first test pad V1. The first control signal SW1 is acquired by the first control pad S1 pad. The second control signal SW2 is acquired by the second control pad S2 pad. For example, a test signal is provided to the first test pad V1 by the external device in a needling manner, and a control signal is provided to the first control pad S1 pad and the second control pad S2 pad by the external device in a needling manner. In the module stage, the first test signal VD1 and the second control signal SW2 are provided by the FPC, and the first control signal SW1 is provided by the driver chip 30. For example, the driver chip 30 provides the first control signal SW1 to the first control pad S1 pad through the third control signal line L6, so that the first control signal SW1 is transmitted to the first control signal line L2.

If a crack occurs in the display panel, the first test signal VD1 may still be transmitted to the corresponding pixel unit PX through the first test signal line L1, the second switch 12, and the second data line DL2, but cannot be transmitted to the corresponding pixel unit PX through the crack detection line PCD. For example, if the first data line DL1 corresponding to the second column of pixel units PX cannot receive the first test signal VD1, the second crack detection line PCD2 breaks, and the second column of pixel units PX presents a bright line, which indicates that a crack occurs on the left half of the display panel. If the first data line DL1 corresponding to the ninth column of pixel units PX cannot receive the first test signal VD1, the first crack detection line PCD1 breaks, and the ninth column of pixel units PX presents a bright line, which indicates that a crack occurs on the right half of the display panel.

When the crack detection mode is switched to the lighting test mode, the crack detection circuit 10 is controlled to turn off in response to the first control signal SW1. At the same time, the lighting test circuit 20 is controlled to turn on in response to the second control signal SW2. The lighting test circuit 20 and the data connection line L5 perform a lighting test on each pixel unit PX.

In the test method of a display panel provided by this embodiment of the present invention, during the crack detection process of the screen body stage and the module stage of the display panel, the same set of crack detection circuits is shared to reduce the number of crack detection circuits. In this manner, it is beneficial to reducing the wiring space of the crack detection circuit, thereby implementing narrow bezel design. The crack detection circuit and the lighting test circuit are separately controlled by using different control signals. In the crack detection mode, the crack detection circuit is controlled to turn on, and the lighting test circuit is controlled to turn off. The crack detection line is configured to detect whether there are cracks on the screen body. In the lighting test mode, the crack detection circuit is controlled to turn off, and the lighting test circuit is controlled to turn on. The data connection line transmits the second test signal to the corresponding data line. Thus, the crack detection line is prevented from adversely affecting the lighting test, thereby improving the accuracy of the lighting test.

An embodiment of the present invention provides a display device. The display device includes the driver chip and the display panel provided by any embodiment of the present invention. As shown in FIGS. 4 to 7, the display panel includes the bonding region. The third control pad S3 pad is disposed in the bonding region. The third control pad S3 pad is connected to the first control signal line L2. For example, the third control pad S3 pad may be connected to the first control pad S1 pad through the third control signal line L6, so that the third control pad S3 pad is connected to the first control signal line L2. The signal output pad SCpad on the driver chip 30 is bonded and connected to the third control pad S3 pad by conductive adhesive. The display device also includes the flexible printed circuit (FPC). The display panel also includes the first test pad V1 pad. The flexible circuit board is configured to be bonded and connected to the first test pad V1 pad in the module stage.

FIG. 9 is a diagram illustrating the structure of a display device according to an embodiment of the present invention. FIG. 9 schematically shows the case where the display device 200 is a mobile phone. In practical applications, the display device 200 may also be any electronic product having a display function, including but not limited to: a television, a laptop, a desktop display, a tablet computer, a digital camera, a smart bracelet, a smart glass, a vehicle-mounted display, medical equipment, industrial control equipment, and a touch interactive terminal. This is not limited in this embodiment of the present invention. The display device 200 provided by this embodiment of the present invention includes the display panel provided in any of the preceding embodiments of the present invention. Thus, the display device provided in this embodiment of the present invention has the functional structure and beneficial effects of the display panel provided in any of the preceding embodiments of the present invention, and the details are not repeated here.

It is to be understood that various forms of processes shown above may be adopted with steps reordered, added or deleted. For example, the steps described in the present invention may be performed in parallel, sequentially, or in different sequences, as long as the desired results of the technical solutions of the present invention can be achieved, and no limitation is imposed herein.

The preceding embodiments do not limit the scope of the present invention. It is to be understood by those skilled in the art that various modifications, combinations, sub-combinations, and substitutions may be performed according to design requirements and other factors. Any modification, equivalent substitution, improvement, or the like made within the spirit and principle of the present invention is within the scope of the present invention.

What is claimed is:

1. A display panel, comprising:
a plurality of pixel units arranged in array,
a plurality of data lines, connected to the plurality of pixel units;
a crack detection line,
a crack detection circuit, connected to the plurality of data lines and the crack detection line,
a first test signal line,
a first control signal line,
a lighting test circuit,
a second test signal line, and
a second control signal line,
wherein the crack detection line is connected between the crack detection circuit and the first test signal line or the crack detection line is connected between the crack detection circuit and the first control signal line; and
wherein the lighting test circuit is connected to the plurality of data lines and is configured to be turned on in response to a signal on the second control signal line, to transmit a test signal on the second test signal line to the plurality of data lines.

2. The display panel according to claim 1, wherein the crack detection circuit comprises at least one first switch and a plurality of second switches, and the plurality of data lines comprise a first data line and a second data line;
the at least one first switch is connected between the first data line and the crack detection line, the crack detection line is connected to the first test signal line, a control terminal of the at least one first switch and the control terminals of the plurality of second switches are connected to the first control signal line, and the at least one first switch is configured to turn on or off the first data lines and the crack detection line in response to a first control signal; and
a second switch of the plurality of second switches is connected between a second data line of the second data lines and the first test signal line, and the plurality of second switches are configured to turn on or off the second data lines and the first test signal line in response to a second control signal.

3. The display panel according to claim 2, different first switches of the at least one first switch and different second switches of the plurality of second switches are connected to different data lines of the plurality of data lines.

4. The display panel according to claim 2, wherein the crack detection circuit comprises two first switches, and the crack detection line comprises a first crack detection line and a second crack detection line; and
one end of the first crack detection line is connected to one of the two first switches, and another end of the first crack detection line is connected to the first test signal line;
one end of the second crack detection line is connected to another first switch of the two first switches, and another end of the second crack detection line is connected to the first test signal line.

5. The display panel according to claim 2, wherein a first switch of the two first switches comprises a first transistor, a first electrode of the first transistor is connected to the first crack detection line or the second crack detection line, a second electrode of the first transistor is connected to the first data line, and a gate of the first transistor is connected to the first control signal line; and
the second switch comprises a second transistor, a first electrode of the second transistor is connected to the second data line, a second electrode of the second transistor is connected to the first test signal line, and a gate of the second transistor is connected to the first control signal line.

6. The display panel according to claim 1, comprising a display region and a non-display region disposed around at least part of the display region, wherein the crack detection circuit and the crack detection line are located in at least part of the non-display region, and the crack detection line is disposed around the display region;
wherein the display panel further comprises a data connection line;
wherein the data connection line, the first test signal line, the second test signal line, the first control signal line and the second control signal line are located in the non-display region; and
the plurality of pixel units are located in the display region, and emitted colors of a plurality of pixel units connected to a same data line of the plurality of data lines are the same.

7. The display panel according to claim 6, wherein the non-display region further comprises a first test pad and a first control pad, the first test signal line is connected to the first test pad, and the first control signal line is connected to the first control pad;
the non-display region further comprises a second test pad and a second control pad, the second test signal line is connected to the second test pad, and the second control signal line is connected to the second control pad.

8. The display panel according to claim 7, wherein the second test pad comprises a first sub-pad, a second sub-pad, and a third sub-pad, the second test signal line comprises a first sub-signal line, a second sub-signal line, and a third sub-signal line, the first sub-signal line is connected to the first sub-pad, the second sub-signal line is connected to the second sub-pad, and the third sub-signal line is connected to the third sub-pad; and a test signal transmitted by the first sub-signal line, a test signal transmitted by the second sub-signal line, and a test signal transmitted by the third sub-signal line are different, and data lines corresponding to different sub-signal lines are different.

9. The display panel according to claim 7, and the lighting test circuit is connected to the plurality of data lines through the data connection line; and
the lighting test circuit comprises a third switch, the third switch comprises a third transistor, a gate of the third transistor is connected to the second control signal line, a first electrode of the third transistor is connected to the second test signal line, and a second electrode of the third transistor is connected to the data connection line.

10. The display panel according to claim 1, wherein the crack detection circuit comprises at least one first switch and a plurality of second switches, and the plurality of data lines comprise a plurality of first data lines and a plurality of second data lines;
the at least one first switch is connected between the first data line and the first test signal line, the crack detection line is connected between a control terminal of the at least one first switch and the first control signal line, and the at least one first switch is configured to turn on or off the first data lines and the first test signal line in response to a first control signal of the first control signal line; and
one of the plurality of second switches is connected between a second data line of the second data lines and the first test signal line, control terminals of the plurality of second switches are connected to the first control signal line, and the plurality of second switches are configured to turn on or off the second data lines and the first test signal line in response to a second control signal of the second control signal line.

11. The display panel according to claim 1, further comprising a first control pad connected to the first control signal line, wherein a first control signal applied to the first control pad is a direct current voltage signal;
the display panel further comprises a bonding region, a third control pad is disposed in the bonding region, and the third control pad is connected to the first control signal line;
the first control signal line is connected to the first control pad;
a first test signal on the first test signal line is a fixed voltage signal;
a size of the first control pad is greater than a size of the third control pad; and
the third control pad is connected to the first control signal line through a third control signal line.

12. A test method of a display panel, wherein the display panel comprises a plurality of data lines and a plurality of pixel units, a crack detection circuit, a crack detection line, a first test signal line, a first control signal line, a lighting test circuit, a data connection line, a second test signal line, and a second control signal line; and
the test method of a display panel comprises:
in a crack detection mode, controlling the crack detection circuit to turn on in response to a first control signal on the first control signal line and controlling the lighting test circuit to turn off in response to a second control signal on the second control signal line;
in a lighting test mode, controlling the crack detection circuit to turn off in response to the first control signal on the first control signal line and controlling the lighting test circuit to turn on in response to the second control signal on the second control signal line.

13. A display device, comprising a driver chip and the display panel according to claim 1.

14. The display device according to claim 13, wherein the display panel comprises a bonding region, a third control pad is disposed in the bonding region, the driver chip is located in the bonding region, and a signal output pad on the driver chip is bonded and connected to the third control pad.

15. The display device according to claim 14, further comprising a flexible printed circuit, the display panel further comprises a first test pad, and the flexible printed circuit is configured to be bonded and connected to the first test pad.
